(19) United States
(12) Patent Application Publication
(10) Pub. No.: US 2025/0295000 A1
(43) Pub. Date: Sep. 18, 2025

(54) PANEL ASSEMBLY, MANUFACTURING DEVICE OF DISPLAY PANEL, MANUFACTURING METHOD OF DISPLAY PANEL

(71) Applicant: Samsung Display Co., Ltd., Yongin-Si (KR)

(72) Inventors: YOUNGSU KIM, Yongin-si (KR); DONGJIN PARK, Yongin-si (KR); KISANG YOO, Yongin-si (KR); SANGHYUCK YOON, Yongin-si (KR)

(21) Appl. No.: 18/977,966

(22) Filed: Dec. 12, 2024

(30) Foreign Application Priority Data
Mar. 14, 2024 (KR) 10-2024-0036033

(51) Int. Cl. H10K 59/80; H10K 102/00

(52) U.S. Cl. CPC H10K 59/871; H10K 2102/311

(57) ABSTRACT

A panel assembly includes a metal plate and a display panel disposed on the metal plate and having a bent portion at at least one corner portion. By pressing the panel assembly from bottom to top, defects such as buckling and wrinkling can be prevented from occurring at corner portion.

This application claims priority to Korean Patent Application No. 10-2024-0036033, filed on Mar. 14, 2024, and all the benefits accruing therefrom under 35 U.S.C. § 119, the content of which in its entirety is herein incorporated by reference.

### BACKGROUND

### 1. Field

Implementations of the inventive concept relate generally to a panel assembly, a manufacturing device of a display panel, and a manufacturing method of a display panel.

### 2. Discussion of the Background

Conventionally, display panels consisting of only flat surfaces have been used, but recently, display panels including various curved surfaces are being used. The display panel may include a plurality of side portions and a corner portion located between two adjacent side portions. When bending the corner portion of the display panel, buckling or wrinkling may occur. Accordingly, the display quality of the display device may deteriorate.

### SUMMARY

Embodiments provide a panel assembly.

Embodiments provide a manufacturing device of a display panel.

Embodiments provide a manufacturing method of a display panel.

A panel assembly according to an embodiment may include a metal plate, and a display panel disposed on the metal plate and having a bent portion at at least one corner portion. The metal plate may have a bent portion in an area corresponding to the bent portion of the display panel.

In an embodiment, the metal plate may include aluminum.

In an embodiment, the panel assembly may further include a resin disposed between the metal plate and the display panel, and adhering the metal plate and the display panel.

In an embodiment, the panel assembly may further include a pressure sensitive adhesive disposed between the metal plate and the display panel, and adhering the metal plate and the display panel.

In an embodiment, edges of the metal plate, the display panel and the pressure sensitive adhesive may be disposed in a straight line.

A manufacturing device according to an embodiment may include a fixing member for fixing a panel assembly, and a pressing member which presses a central portion of the panel assembly from bottom to top.

In an embodiment, the panel assembly may include a metal plate, and a display panel disposed on the metal plate and having flexible characteristics at least one corner portion.

In an embodiment, the fixing member may fix an outer portion of the metal plate. In an embodiment, while the pressing member presses the central portion of the panel assembly, the corner portion of the display panel may be bent.

In an embodiment, while the pressing member presses the central portion of the panel assembly, a tensile force may occur in the panel assembly.

In an embodiment, the panel assembly may further include a resin disposed between the metal plate and the display panel, and adhering the metal plate and the display panel.

In an embodiment, the panel assembly may further include a pressure sensitive adhesive disposed between the metal plate and the display panel, and adhering the metal plate and the display panel, and a dummy portion disposed on the pressure sensitive adhesive and surrounding the corner portion of the display panel.

In an embodiment, the fixing member may fix an outer portion of the metal plate and the dummy portion.

A manufacturing method according to an embodiment may include forming a panel assembly, fixing the panel assembly to a manufacturing device, and pressing a central portion of the panel assembly from bottom to top.

In an embodiment, the panel assembly may include a metal plate, and a display panel disposed on the metal plate and having flexible characteristics at least one corner portion.

In an embodiment, while the pressing member presses the panel assembly, the corner portion of the display panel may be bent.

In an embodiment, while the pressing member presses the panel assembly, a tensile force may occur in the panel assembly.

In an embodiment, while the panel assembly is fixed to a manufacturing device, an outer portion of the metal plate may be fixed.

In an embodiment, the manufacturing method may further include removing the outer portion, after the pressing the central portion of the panel assembly.

Therefore, in the manufacturing method of a display panel according to embodiments of the present inventive concept, the panel assembly may be fixed and may be pressed from bottom to top. Accordingly, only tensile force may occur in the panel assembly. Therefore, compressive deformation may not be applied to the corner portion, and defects such as buckling and wrinkling can be prevented from occurring in the corner portion having a three-dimensional curved shape.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view illustrating a display panel manufactured according to a manufacturing method of a display panel according to embodiments of the present inventive concept.

FIG. 2 is an enlarged view of area A of FIG. 1.

FIG. 3 is a block diagram illustrating the display panel of FIG. 1.

FIG. 4 is a circuit diagram illustrating a pixel included in the display panel of FIG. 3.

FIGS. 5, 6, 7, 8 and 9 are diagrams illustrating a manufacturing method of a display panel according to an embodiment of the present inventive concept.

FIGS. 10, 11, 12, 13 and 14 are diagrams illustrating a manufacturing method of a display panel according to an embodiment of the present inventive concept.

### DETAILED DESCRIPTION

Illustrative, non-limiting embodiments will be more clearly understood from the following detailed description in conjunction with the accompanying drawings.

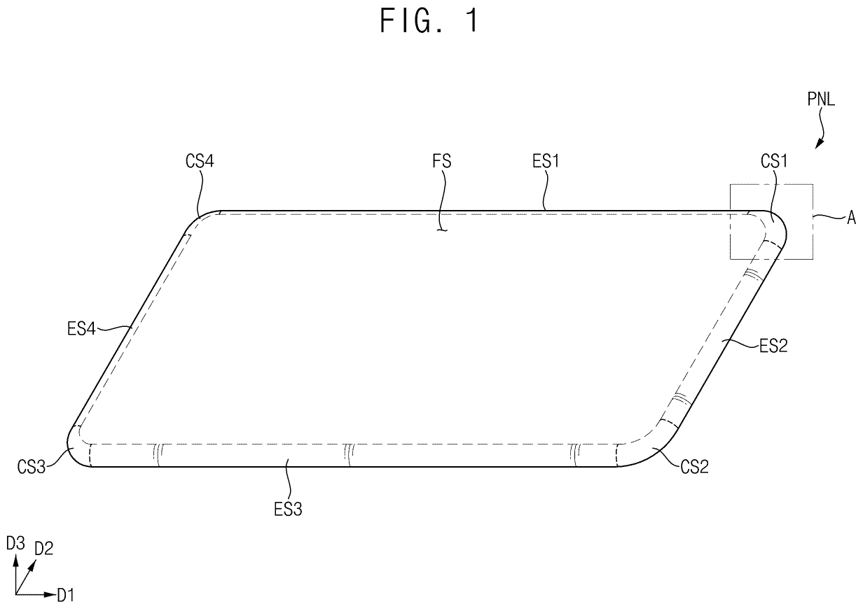

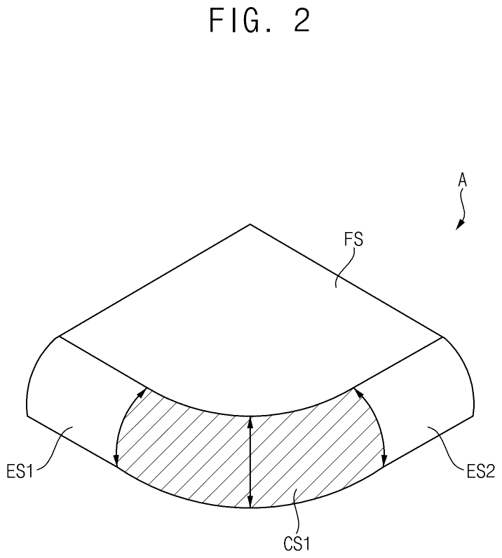

FIG. 1 is a plan view illustrating a display panel manufactured according to a manufacturing method of a display panel according to embodiments of the present inventive concept. FIG. 2 is an enlarged view of area A of FIG. 1.

Referring to FIG. 1, a display panel PNL manufactured according to a manufacturing method of a display panel according to the embodiments of the present inventive concept may have a flat portion FS, first to fourth side portions ES1, ES2, ES3, and ES4, and first to fourth corner portions CS1, CS2, CS3, and CS4.

The flat portion FS may have a flat surface. For example, the flat portion FS may be parallel to a plane defined by a first direction D1 and a second direction D2 intersecting the first direction D1. An image may be displayed through the flat portion FS, and the flat portion FS may be the main display surface of the display panel PNL.

The first to fourth side portions ES1, ES2, ES3, and ES4 may extend from the flat portion FS. For example, the first and third portions ES1 and ES3 may contact the long side of the flat portion FS, and the second and fourth side portions ES2 and ES4 may contact the short side of the flat portion FS. An image may be displayed on the first to fourth portions ES1, ES2, ES3, and ES4.

The first to fourth corner portions CS1, CS2, CS3, and CS4 may extend from the flat portion FS and the first to fourth side portions ES1, ES2, ES3, and ES4. For example, the first corner portion CS1 may contact the flat portion FS, the first side portion ES1, and the second side portion ES2, the second corner portion CS2 may contact the flat portion FS, the second side portion ES2, and the third side portion ES3, the third corner portion CS3 may contact the flat portion FS, the third side portion ES3, and the fourth side portion ES3, and the fourth corner portion CS4 may contact the flat portion FS, the fourth side portion ES4, and the first side portion ES1. An image may be displayed through the first to fourth corner portions CS1, CS2, CS3, and CS4.

Referring to FIG. 2, the display panel PNL may have flexible characteristics at least one side portion and/or at least one corner portion. For example, the above-described side portions and the above-described corner portions may be bent.

In an embodiment, each of the first and second side portions ES1 and ES2 may have a two-dimensional curved shape. Here, the two-dimensional curved shape may be a shape in which a plane is bent in one direction. For example, the first side portion ES1 may be bent from the flat portion FS in one direction.

In an embodiment, the first corner portion CS1 may have a three-dimensional curved shape. Here, the three-dimensional curved shape may be a shape in which a plane is bent in two or more directions. For example, the first corner portion CS1 may be bent in a plurality of directions between two directions perpendicular to each other.

As images are displayed through the flat portion FS, the first to fourth side portions ES1, ES2, ES3, and ES4, and the first to fourth corner portions CS1, CS2, CS3, and CS4, the satisfaction of users using the display panel PNL can be improved.

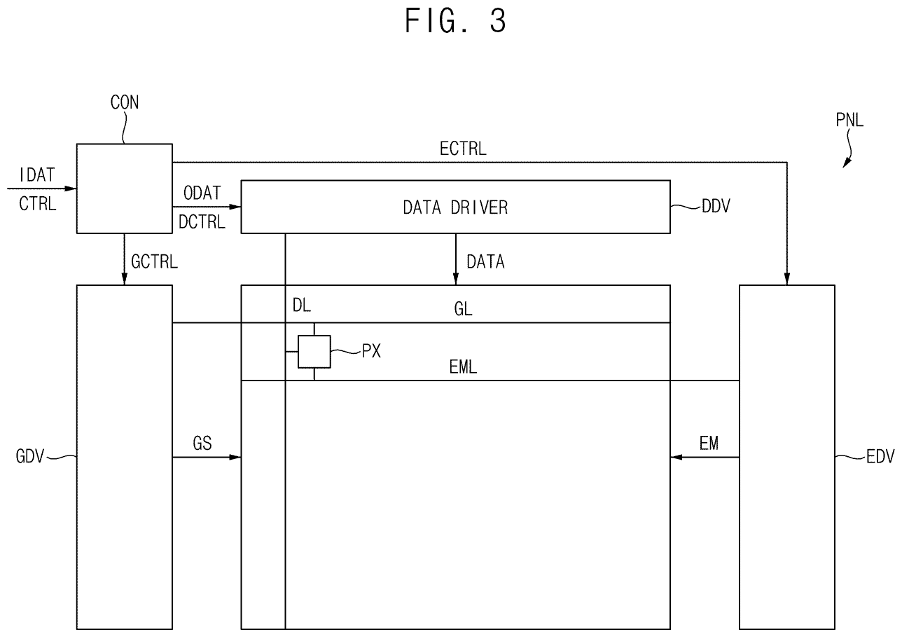

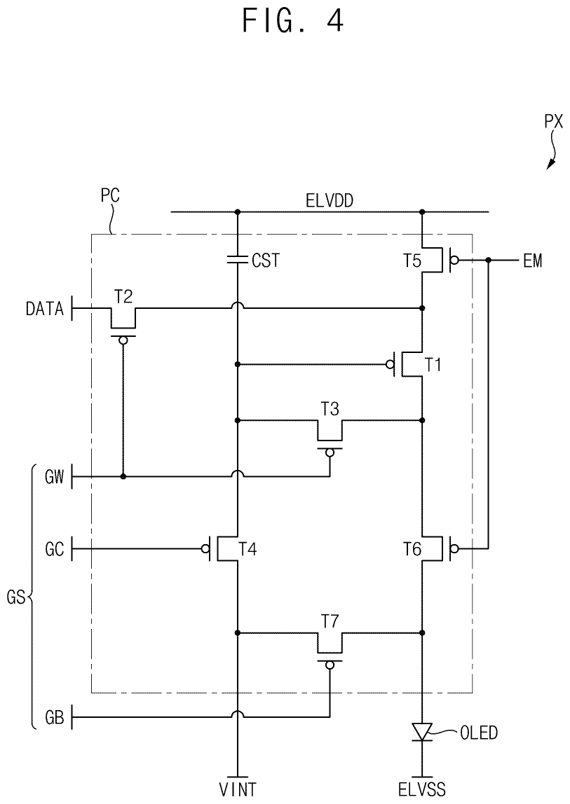

FIG. 3 is a block diagram illustrating the display panel of FIG. 1. FIG. 4 is a circuit diagram illustrating a pixel included in the display panel of FIG. 3.

Referring to FIG. 3, the display panel PNL may include a pixel PX, a data driver DDV, a gate driver GDV, an emission driver EDV, and a controller CON.

The data driver DDV may generate a data voltage DATA based on an output image data ODAT and a data control signal DCTRL. In addition, the data driver DDV may generate the data voltage DATA corresponding to the output image data ODAT and may output the data voltage DATA in response to the data control signal DCTRL. The data voltage DATA may be transmitted to the pixel PX through a data line DL. The data control signal DCTRL may include an output data enable signal, a horizontal start signal, and a load signal. For example, the data driver DDV may be implemented with one or more integrated circuits (“IC”s).

The gate driver GDV may generate a gate signal GS based on a gate control signal GCTRL. The gate signal GS may be transmitted to the pixel PX through a gate line GL. For example, the gate signal GS may include a first gate signal GW, a second gate signal GC, and a third gate signal GB. Each of the first to third gate signals GW, GC, and GB may include a gate-on voltage that turns on the transistor and a gate-off voltage that turns off the transistor. The gate control signal GCTRL may include a vertical start signal, a clock signal, etc.

The emission driver EDV may generate an emission driving signal EM based on an emission control signal ECTRL. The emission driving signal EM may be transmitted to the pixel PX through an emission control line EML. The emission driving signal EM may include a gate-on voltage and a gate-off voltage. The gate-on voltage and the gate-off voltage included in the emission driving signal EM may have the same voltage as the gate-on voltage and the gate-off voltage included in the gate signal GS. The emission driving signal EM may include a vertical start signal, a clock signal, etc.

The controller CON (e.g., a timing controller (T-CON)) may receive an input image data IDAT and a control signal CTRL from an external host processor (e.g., GPU). For example, the input image data IDAT may be RGB data including red image data, green image data, and blue image data. The control signal CTRL may include a vertical synchronization signal, a horizontal synchronization signal, an input data enable signal, and a master clock signal. The controller CON may generate the gate control signal GCTRL, the emission control signal ECTRL, the data control signal DCTRL, and the output image data ODAT based on the input image data IDAT and the control signal CTRL.

Referring to FIG. 4, the pixel PX may include a pixel circuit PC and at least one organic light emitting diode OLED. The pixel circuit PC may provide driving current to the organic light emitting diode OLED.

In an embodiment, the pixel circuit PC may include a plurality of transistors and at least one storage capacitor. For example, the pixel circuit PC may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal (e.g., a source terminal), and a second terminal (e.g., a drain terminal). The gate terminal of the first transistor T1 may be connected to the storage capacitor CST. The first terminal of the first transistor T1 may be provided with a high power voltage EVLDD. The second terminal of the first transistor T1 may be connected to the sixth transistor T6. The first transistor T1 may generate the driving current based on the data voltage DATA.

The second transistor T2 may include a gate terminal, a first terminal (e.g., a source terminal), and a second terminal (e.g., a drain terminal). The gate terminal of the second transistor T2 may receive the first gate signal GW through the gate line GL. The first terminal of the second transistor T2 may receive the data voltage DATA. The second terminal of the second transistor T2 may provide the data voltage DATA to the first transistor T1.

The second transistor T2 may be turned on or off in response to the first gate signal GW. For example, when the second transistor T2 is a PMOS transistor, the second transistor T2 may be turned off when the first gate signal GW has a positive voltage level, and may be turned on when the first gate signal GW has a negative voltage level.

The third transistor T3 may include a gate terminal, a first terminal (e.g., a source terminal), and a second terminal (e.g., a drain terminal). The gate terminal of the third transistor T3 may receive the first gate signal GW. The first terminal of the third transistor T3 may be connected to the second terminal of the first transistor T1, and the second terminal of the third transistor T3 may be connected to the gate terminal of the first transistor T1.

The third transistor T3 may be turned on or off in response to the first gate signal GW. For example, when the third transistor T3 is a PMOS transistor, the third transistor T3 may be turned on when the first gate signal GW has a negative voltage level, and may be turned off when the first gate signal GW has a positive voltage level. During a period in which the third transistor T3 is turned on in response to the first gate signal GW, the third transistor T3 may diode-connect the first transistor T1. Accordingly, the third transistor T3 may compensate for the threshold voltage of the first transistor T1.

The fourth transistor T4 may include a gate terminal, a first terminal (e.g., a source terminal), and a second terminal (e.g., a drain terminal). The gate terminal of the fourth transistor T4 may receive the second gate signal GC. The fourth transistor T4 may transmit an initialization voltage VINT to the gate terminal of the first transistor T1.

The fourth transistor T4 may be turned on or off in response to the second gate signal GC. For example, when the fourth transistor T4 is a PMOS transistor, the fourth transistor T4 may be turned on when the second gate signal GC has a negative voltage level, and may be turned off when the second gate signal GC has a positive voltage level.

While the fourth transistor T4 is turned on in response to the second gate signal GC, the initialization voltage VINT may be provided to the gate terminal of the first transistor T1. Accordingly, the gate terminal of the first transistor T1 may be initialized to the initialization voltage VINT.

The fifth transistor T5 may include a gate terminal, a first terminal (e.g., a source terminal), and a second terminal (e.g., a drain terminal). The gate terminal of the fifth transistor T5 may receive the emission driving signal EM. The first terminal of the fifth transistor T5 may receive the high power voltage ELVDD. The second terminal of the fifth transistor T5 may be connected to the first transistor T1. When the fifth transistor T5 is turned on in response to the emission driving signal EM, the fifth transistor T5 may provide the high power voltage ELVDD to the first transistor T1.

The sixth transistor T6 may include a gate terminal, a first terminal (e.g., a source terminal), and a second terminal (e.g., a drain terminal). The gate terminal of the sixth transistor T6 may receive the emission driving signal EM. The first terminal of the sixth transistor T6 may be connected to the first transistor T1. The second terminal of the sixth transistor T6 may be connected to the organic light emitting diode OLED. When the sixth transistor T6 is turned on in response to the emission driving signal EM, the sixth transistor T6 may provide the driving current to the organic light emitting diode OLED.

The seventh transistor T7 may include a gate terminal, a first terminal (e.g., a source terminal), and a second terminal (e.g., a drain terminal). The gate terminal of the seventh transistor T7 may receive the third gate signal GB. The second terminal of the seventh transistor T7 may receive the initialization voltage VINT. The first terminal of the seventh transistor T7 may be connected to the organic light emitting diode OLED. When the seventh transistor T7 is turned on in response to the third gate signal GB, the seventh transistor T7 may provide the initialization voltage VINT to the organic light emitting diode OLED. Accordingly, the seventh transistor T7 may initialize the first terminal of the organic light emitting diode OLED to the initialization voltage VINT.

The storage capacitor CST may include a first terminal and a second terminal. The first terminal of the storage capacitor CST may be connected to the gate terminal of the first transistor T1, and the second terminal of the storage capacitor CST may receive the high power voltage ELVDD. The storage capacitor CST may maintain the voltage level of the gate terminal of the first transistor T1 during the deactivation period of the first gate signal GW.

The organic light emitting diode OLED may include a first terminal (e.g., anode terminal) and a second terminal (e.g., cathode terminal). The first terminal of the organic light emitting diode OLED may receive the driving current, and the second terminal may receive a low power voltage ELVSS. The organic light emitting diode OLED may generate light with luminance corresponding to the driving current.

The connection structure of the pixel circuit PC and the organic light emitting diode OLED shown in FIG. 4 is an example and may be changed in various ways.

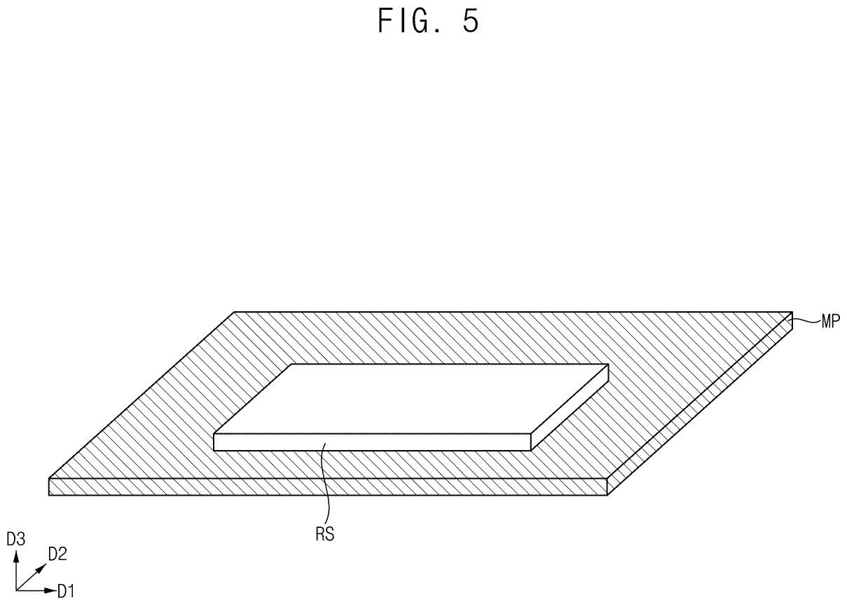

FIGS. 5 to 9 are diagrams illustrating a manufacturing method of a display panel according to an embodiment of the present inventive concept.

A manufacturing method of a display panel according to an embodiment of the present inventive concept may include forming a panel assembly, fixing the panel assembly, pressing the panel assembly, and separating the panel assembly. This will be explained in detail below.

As shown in FIG. 5, a resin RS may be formed on a metal plate MP.

The metal plate MP may transmit pressure to the display panel PNL. For example, tensile strain of the metal plate MP may be transmitted to the display panel PNL. The metal plate MP may have a rigidity similar to that of the display panel PNL.

In an embodiment, the metal plate MP may include a metal material. Examples of metal materials that can be used as the metal plate MP may include aluminum, magnesium, titanium, steel, and stainless steel (SUS).

The resin RS may be disposed on the metal plate MP and may adhere the metal plate MP to the display panel PNL. In an embodiment, the resin RS may be disposed in a central portion of the metal plate MP and may be formed through an inkjet printing process.

The resin RS may transmit pressure from the metal plate MP to the display panel PNL. Accordingly, the resin RS may have a relatively high modulus. The resin may be a pressure sensitive adhesive PSA.

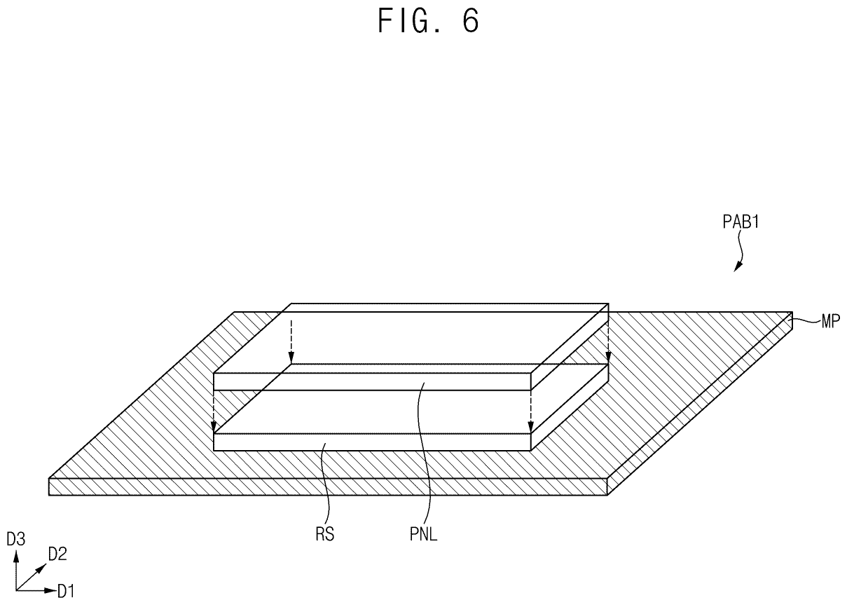

As shown in FIG. 6, the display panel PNL may be disposed on the resin RS. Accordingly, the display panel PNL may be laminated on the metal plate MP. For example, the metal plate MP and the display panel PNL may be adhered to each other using the resin RS. Accordingly, a pre-panel assembly PPAB1 including the metal plate MP, the resin RS, and the display panel PNL may be formed.

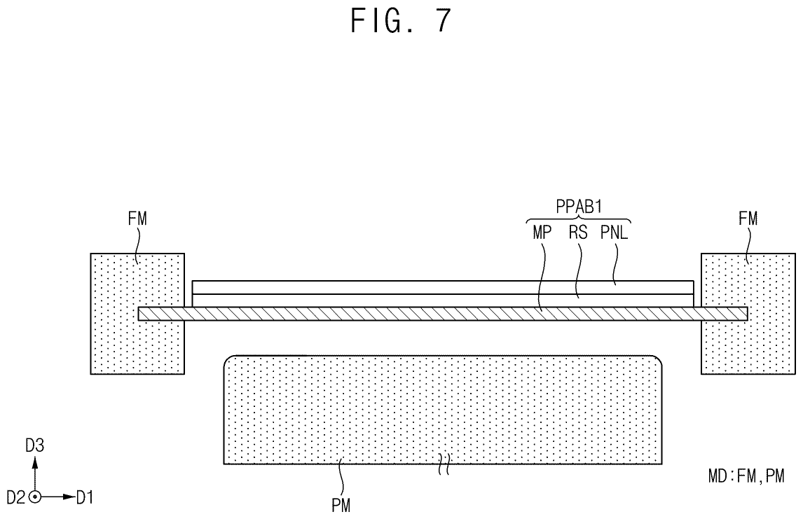

As shown in FIG. 7, the pre-panel assembly PPAB1 may be loaded to the manufacturing device MD. In an embodiment, the manufacturing device MD may include a fixing member FM and a pressing member PM.

In an embodiment, the fixing member FM may fix the pre-panel assembly PPAB1. For example, the fixing member FM may be a gripper and may fix an outer portion of the metal plate MP.

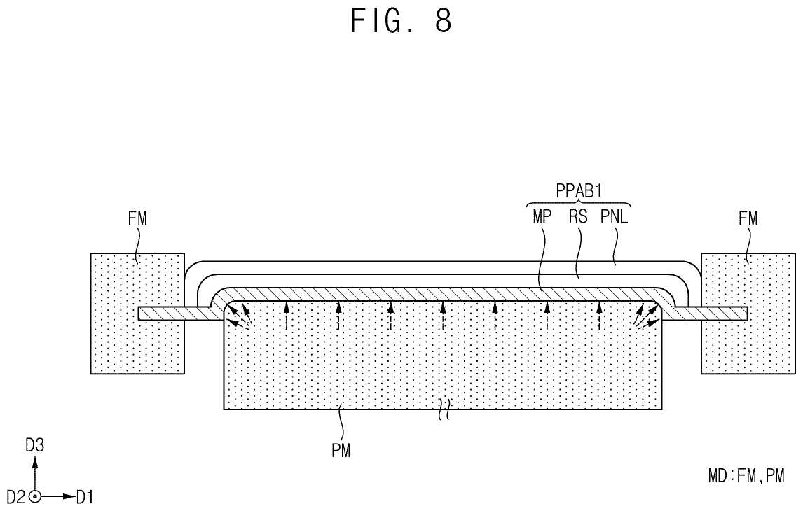

As shown in FIG. 8, the pre-panel assembly PPAB1 may be bent.

In an embodiment, the pressing member PM may press a central portion of the pre-panel assembly PPAB1 from bottom to top. For example, the pressing member PM may contact the metal plate MP. In addition, the pressing member PM may press the metal plate MP to a third direction D3, a thickness direction of the panel assembly PAB1, which is perpendicular to the first and second directions D1 and D2.

When the pressing member PM applies back pressure to the metal plate MP, a tensile force may occur in the metal plate MP. Tensile strain occurring in the metal plate MP may be transmitted to the display panel PNL through the resin RS, and the tensile force may also occur in the display panel PNL. Accordingly, while the pressing member PM presses the central portion of the pre-panel assembly PPAB1, the tensile force may occur in the pre-panel assembly PPAB1 and the corner portion of the display panel PNL may be bent.

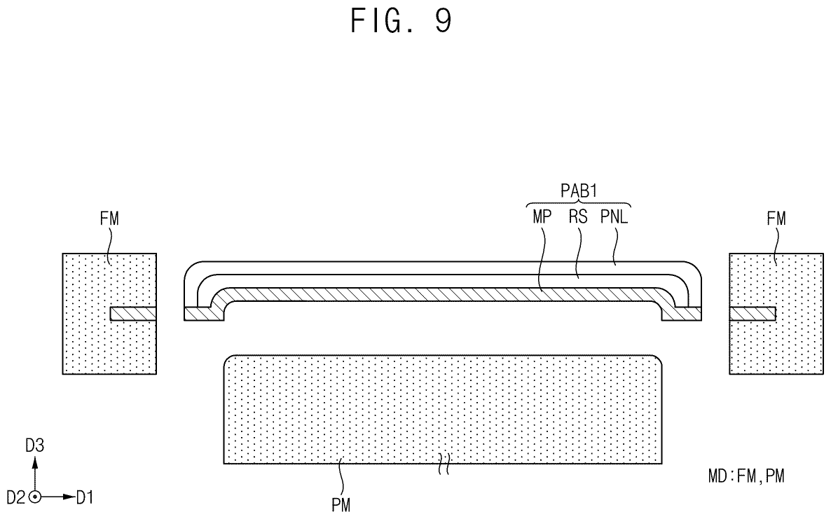

As shown in FIG. 9, the panel assembly PAB1 may be separated from the manufacturing device MD. In addition, the outer portion of the metal plate MP which is not covered by the resin RE and the display panel PNL may be removed from the pre-panel assembly PPAB1.

In the manufacturing method of a display panel according to an embodiment of the present inventive concept, the pre-panel assembly may be fixed and pressed from bottom to top. Accordingly, only tensile force may occur in the panel assembly. Therefore, compressive deformation may not be applied to the corner portion, and defects such as buckling and wrinkling can be prevented from occurring in the corner portion having a three-dimensional curved shape.

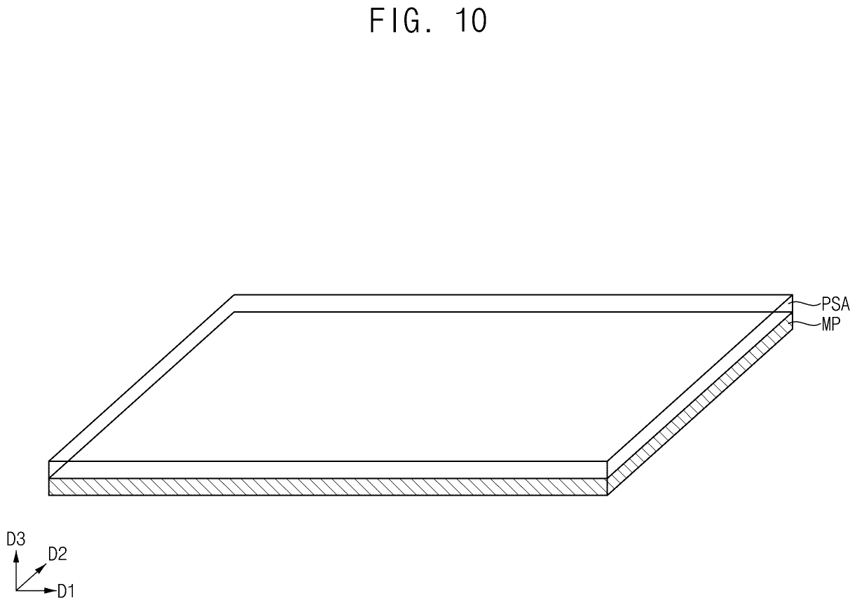

FIGS. 10 to 14 are diagrams illustrating a manufacturing method of a display panel according to an embodiment of the present inventive concept.

A manufacturing method of a display panel according to an embodiment of the present inventive concept may include forming a panel assembly, fixing the panel assembly, pressing the panel assembly, and separating the panel assembly. This will be explained in detail below.

As shown in FIG. 10, a pressure sensitive adhesive PSA may be formed on the metal plate MP.

The metal plate MP may transmit pressure to the display panel PNL. For example, tensile strain of the metal plate MP may be transmitted to the display panel PNL. The metal plate MP may have a rigidity similar to that of the display panel PNL.

In an embodiment, the metal plate MP may include a metal material. Examples of metal materials that can be used as the metal plate MP may include aluminum, magnesium, titanium, steel, and stainless steel (SUS).

The pressure sensitive adhesive PSA may be disposed on the metal plate MP and may adhere the metal plate MP to the display panel PNL. In an embodiment, the pressure sensitive adhesive PSA may be formed entirely on the top of the metal plate MP.

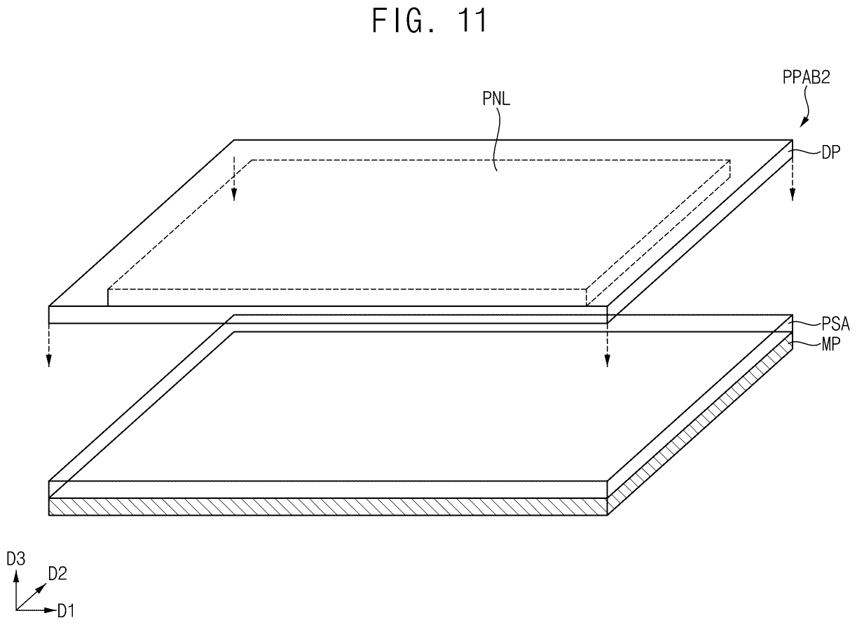

As shown in FIG. 11, the display panel PNL and a dummy portion DP may be disposed on the pressure sensitive adhesive PSA. The dummy portion DP may be formed to surround a corner portion of the display panel PNL. Accordingly, the display panel PNL may be laminated to the metal plate MP. For example, the display panel PNL may be attached to the central portion of the metal plate MP, and the dummy portion DP may be attached to the outer portion of the metal plate MP. Accordingly, a pre-panel assembly PPAB2 including the metal plate MP, the pressure sensitive adhesive PSA, the dummy portion DP, and the display panel PNL may be formed.

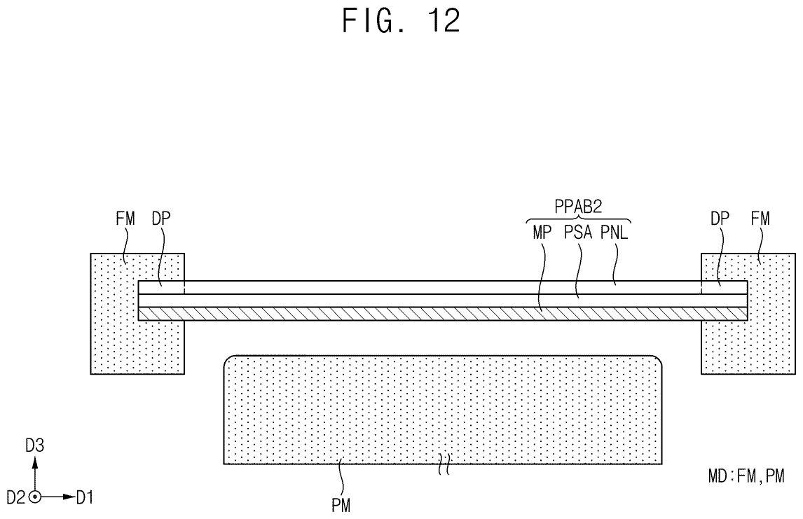

As shown in FIG. 12, the pre-panel assembly PPAB2 may be loaded to the manufacturing device MD. In an embodiment, the manufacturing device MD may include a fixing member FM and a pressing member PM.

In an embodiment, the fixing member FM may fix the pre-panel assembly PPAB2 to the manufacturing device MD. For example, the fixing member FM may be a gripper and may fix the outer portion of the metal plate MP and the dummy portion DP.

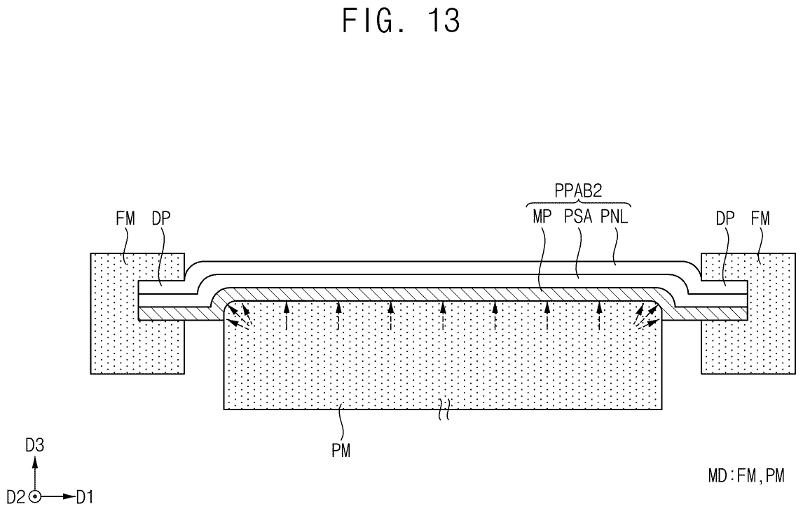

As shown in FIG. 13, the panel assembly PAB1 may be bent.

In an embodiment, the pressing member PM may press a central portion of the pre-panel assembly PPAB2 from bottom to top. For example, the pressing member PM may contact the metal plate MP. In addition, the pressing member PM may press the metal plate MP to the third direction D3.

When the pressing member PM applies back pressure to the metal plate MP, a tensile force may occur in the metal plate MP. Tensile strain occurring in the metal plate MP may be transmitted to the display panel PNL through the pressure sensitive adhesive PSA, and the tensile force may also occur in the display panel PNL. Accordingly, while the pressing member PM presses the central portion of the pre-panel assembly PPAB2, the tensile force may occur in the pre-panel assembly PPAB2 and the corner portion of the display panel PNL may be bent.

In an embodiment, the dummy portion DP may improve a difference in deformation between the metal plate MP and the display panel PNL according to the characteristics of the pressure sensitive adhesive (PSA).

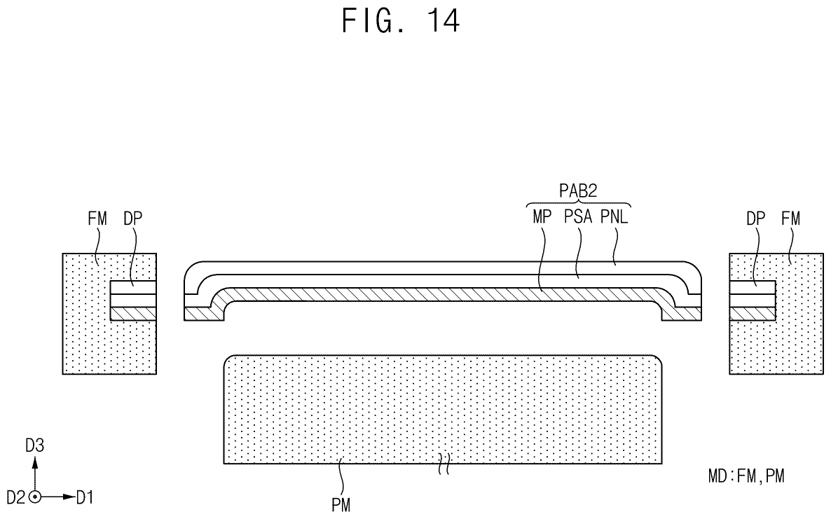

As shown in FIG. 14, the panel assembly PAB2 may be separated from the manufacturing device MD. In addition, the outer portion of the metal plate MP and the dummy portion DP may be removed from the panel assembly PAB2.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A panel assembly comprising:
a metal plate; and
a display panel disposed on the metal plate and having a bent portion at at least one corner portion,
wherein the metal plate has a bent portion in an area corresponding to the bent portion of the display panel.

2. The panel assembly of claim 1, wherein the metal plate includes aluminum.

3. The panel assembly of claim 1, further comprising:
a resin disposed between the metal plate and the display panel, and adhering the metal plate and the display panel.

4. The panel assembly of claim 1, further comprising:
a pressure sensitive adhesive disposed between the metal plate and the display panel, and adhering the metal plate and the display panel.

5. The panel assembly of claim 4, wherein edges of the metal plate, the display panel and the pressure sensitive adhesive are disposed in a straight line.

6. A manufacturing device of display panel, the manufacturing device comprising:
a fixing member for fixing a panel assembly; and
a pressing member which presses a central portion of the panel assembly from bottom to top.

7. The manufacturing device of claim 6, wherein the panel assembly includes:
a metal plate; and
a display panel disposed on the metal plate and having flexible characteristics at least one corner portion.

8. The manufacturing device of claim 7, wherein the fixing member fixes an outer portion of the metal plate.

9. The manufacturing device of claim 7, wherein, while the pressing member presses the central portion of the panel assembly, the corner portion of the display panel is bent.

10. The manufacturing device of claim 9, wherein, while the pressing member presses the central portion of the panel assembly, a tensile force occurs in the panel assembly.

11. The manufacturing device of claim 7, wherein the panel assembly further includes:
a resin disposed between the metal plate and the display panel, and adhering the metal plate and the display panel.

12. The manufacturing device of claim 7, wherein the panel assembly further includes:
a pressure sensitive adhesive disposed between the metal plate and the display panel, and adhering the metal plate and the display panel; and
a dummy portion disposed on the pressure sensitive adhesive and surrounding the corner portion of the display panel.

13. The manufacturing device of claim 12, wherein the fixing member fixes an outer portion of the metal plate and the dummy portion.

14. A manufacturing method of a display panel, the manufacturing method comprising:
forming a panel assembly;
fixing the panel assembly to a manufacturing device; and
pressing a central portion of the panel assembly from bottom to top.

15. The manufacturing method of claim 14, wherein the panel assembly includes:
a metal plate; and
a display panel disposed on the metal plate and having flexible characteristics at least one corner portion.

16. The manufacturing method of claim 15, wherein, while the pressing member presses the panel assembly, the corner portion of the display panel is bent.

17. The manufacturing method of claim 16, wherein, while the pressing member presses the panel assembly, a tensile force occurs in the panel assembly.

18. The manufacturing method of claim 15, wherein while the panel assembly is fixed to a manufacturing device, an outer portion of the metal plate is fixed.

19. The manufacturing method of claim 18, further comprising:
removing the outer portion after the pressing the central portion of the panel assembly.
